(19) United States
(12) Patent Application Publication
(10) Pub. No.: US 2016/0272481 A1
(43) Pub. Date: Sep. 22, 2016

(54) MEMS DEVICE

(71) Applicant: KABUSHIKI KAISHA TOSHIBA, Tokyo (JP)

(72) Inventors: Hiroaki YAMAZAKI, Yokohama Kanagawa (JP); Yoshihiko KURUI, Yokohama Kanagawa (JP); Tamio IKEHASHI, Yokohama Kanagawa (JP)

(73) Assignee: KABUSHIKI KAISHA TOSHIBA, Tokyo (JP)

(21) Appl. No.: 15/067,110

(22) Filed: Mar. 10, 2016

(30) Foreign Application Priority Data
Mar. 16, 2015 (JP) 2015-052419

(51) Int. Cl. B81B 3/00

(52) U.S. Cl. CPC B81B 3/0008; B81B 2203/04

(57) ABSTRACT

According to one embodiment, a MEMS device is disclosed. The device includes a substrate, a first electrode fixed on the substrate. The first electrode includes a first one end portion and a first other end portion. A capacitor insulating film is provided on the first electrode. An insulating film is provided on the substrate and located around a periphery of the first electrode. A second electrode is provided above the first electrode and movable. The second electrode includes a second one end portion corresponding to the first one end portion, and a second other end portion corresponding to the first other end portion. The second one end portion extends outside the first one end portion and includes a first bent portion bent downward.

### CROSS-REFERENCE TO RELATED APPLICATIONS

This application is based upon and claims the benefit of priority from Japanese Patent Application No. 2015-052419, filed Mar. 16, 2015, the entire contents of which are incorporated herein by reference.

### FIELD

Embodiments described herein relate generally to a micro-electromechanical systems (MEMS) device.

### BACKGROUND

A MEMS device comprises a substrate, a fixed electrode (lower electrode) formed on the substrate and a movable electrode (upper electrode) formed above the fixed electrode. A gap between the upper electrode and the lower electrode is changed by electrostatic attraction produced by providing a potential difference between the lower electrode and the upper electrode. The capacitance can thereby be changed. The MEMS device has a problem (stiction failure) that the upper electrode is not separated from the lower electrode after the upper electrode contacts the lower electrode, and a problem (performance degradation) that the capacitance decreases in a state (down state) where the upper electrode is pulled down toward the lower electrode.

### BRIEF DESCRIPTION OF THE DRAWINGS

FIG. 1 is a plan view showing a MEMS device of a first embodiment.

FIG. 2 is a cross-sectional view seen along one-dot chain line 2-2 in FIG. 1.

FIG. 3 is a perspective view schematically showing a fixed electrode, a movable electrode and a dummy spring portion of the MEMS device of the embodiment.

FIG. 4A is a cross-sectional view showing the MEMS device of the embodiment in a pull-in state.

FIG. 4B is a cross-sectional view showing the MEMS device of the embodiment in a down state.

FIG. 5 is a cross-sectional view showing a modified example of the MEMS device of the first embodiment.

FIG. 6 is a cross-sectional view showing a method for manufacturing the MEMS device shown in FIG. 5.

FIG. 7 is a cross-sectional view showing the method for manufacturing the MEMS device following FIG. 6.

FIG. 8 is a cross-sectional view showing the method for manufacturing the MEMS device following FIG. 7.

FIG. 9 is a cross-sectional view showing the method for manufacturing the MEMS device following FIG. 8.

FIG. 10 is a cross-sectional view showing the method for manufacturing the MEMS device following FIG. 9.

FIG. 11 is a cross-sectional view showing the method for manufacturing the MEMS device following FIG. 10.

FIG. 12 is a cross-sectional view showing the method for manufacturing the MEMS device following FIG. 11.

FIG. 13 is a cross-sectional view showing a modified example of the method for manufacturing the MEMS device of the first embodiment.

FIG. 14 is a cross-sectional view showing a MEMS device obtained by the modified example of the method for manufacturing the MEMS device of the first embodiment.

FIG. 15 is a plan view showing a modified example of the method for manufacturing the MEMS device of the first embodiment.

FIG. 16 is a cross-sectional view showing a MEMS device of a second embodiment.

FIG. 17 is a cross-sectional view showing a method for manufacturing the MEMS device of the second embodiment.

FIG. 18 is a cross-sectional view showing the method for manufacturing the MEMS device following FIG. 17.

FIG. 19 is a cross-sectional view showing the method for manufacturing the MEMS device following FIG. 18.

FIG. 20 is a cross-sectional view showing the method for manufacturing the MEMS device following FIG. 19.

FIG. 21 is a cross-sectional view showing the method for manufacturing the MEMS device following FIG. 20.

FIG. 22 is a cross-sectional view showing a MEMS device of a third embodiment.

FIG. 23 is a cross-sectional view showing a method for manufacturing the MEMS device of the third embodiment.

FIG. 24 is a cross-sectional view showing the method for manufacturing the MEMS device following FIG. 23.

FIG. 25 is a cross-sectional view showing a modified example of the MEMS device of the third embodiment.

FIG. 26 is a plan view showing a MEMS device of another embodiment.

FIG. 27 is a cross-sectional view seen along one-dot chain line 27-27 in FIG. 26.

FIG. 28A is a cross-sectional view showing the MEMS device of the another embodiment in a pull-in state.

FIG. 28B is a cross-sectional view showing the MEMS device of the another embodiment in a down state.

FIG. 29A is a cross-sectional view showing a MEMS device (in an up state) of yet another embodiment.

FIG. 29B is a cross-sectional view showing a MEMS device (in a pull-in state) of the yet another embodiment.

FIG. 29C is a cross-sectional view showing a MEMS device (in a down state) of the yet another embodiment.

FIG. 30 is a diagram for explaining a height which defined a degree of bend of bent portion of a movable electrode.

FIG. 31 is a cross-sectional view showing a method for manufacturing the MEMS device of the yet another embodiment.

FIG. 32 is a cross-sectional view showing the method for manufacturing the MEMS device following FIG. 31.

FIG. 33 is a cross-sectional view showing the method for manufacturing the MEMS device following FIG. 32.

FIG. 34 is a cross-sectional view showing the method for manufacturing the MEMS device following FIG. 33.

FIG. 35 is a cross-sectional view showing the method for manufacturing the MEMS device following FIG. 34.

### DETAILED DESCRIPTION

In general, according to one embodiment, a MEMS device is disclosed. The device includes a substrate, a first electrode fixed on the substrate. The first electrode includes a first one end portion and a first other end portion. A capacitor insulating film is provided on the first electrode. An insulating film is provided on the substrate and located around a periphery of the first electrode. A second electrode is provided above the first electrode and movable. The second electrode includes a second one end portion corresponding to the first one end portion, and a second other end portion corresponding to the first other end portion. The second one end portion extends outside the first one end portion and includes a first bent portion bent downward.

Various embodiments will be described hereinafter with reference to the accompanying drawings. The drawings schematically or conceptually show the embodiments. Thus, a size, ratio and the like shown in the drawings are not necessary equal to those in reality. In the drawings, the same or corresponding portions are represented by the same reference number and their overlapping descriptions are provided as necessary.

### First Embodiment

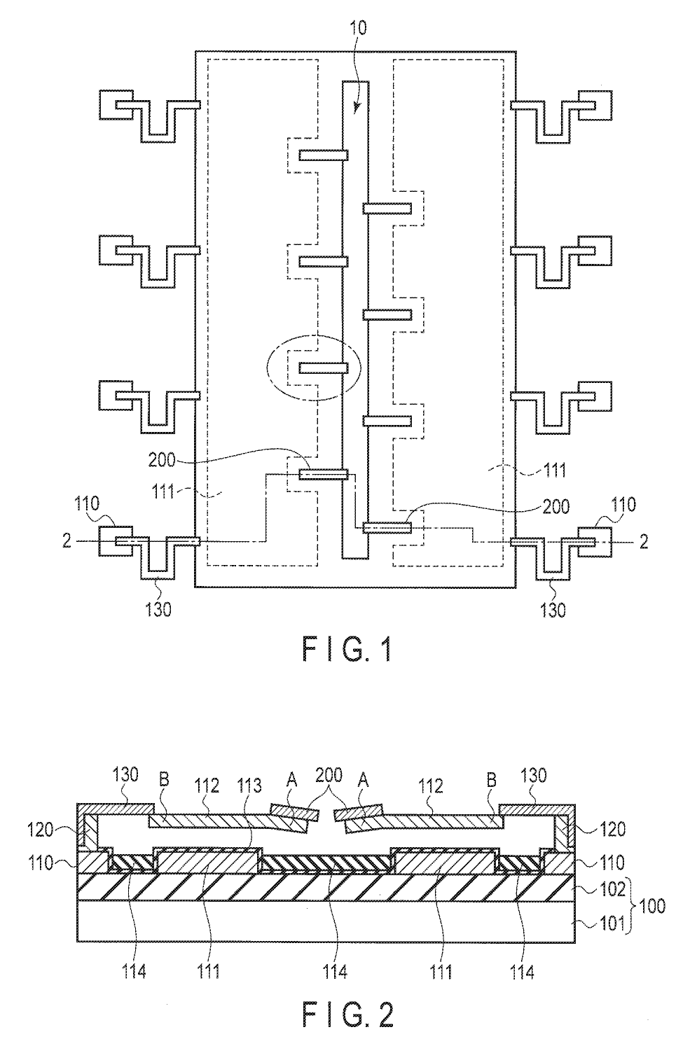

FIG. 1 is a plan view showing a MEMS device of a first embodiment. FIG. 2 is a cross-sectional view seen along one-dot chain line 2-2 in FIG. 1. More specifically, FIG. 2 is a cross-sectional view showing the MEMS device of the embodiment in an up state. The up state is a state where a movable electrode 112 is in a high position resulting from pulling up the movable electrode 112 in a down state from a fixed electrodes 111 side.

The fixed electrodes 111 are fixed on a substrate 100. The substrate 100 comprises a semiconductor substrate 101 and an insulating film 102 provided on the semiconductor substrate 101. The fixed electrodes 111 are fixed on the insulating film 102. The semiconductor substrate 101 is, for example, a silicon substrate. A semiconductor substrate such as an SOI substrate may be used instead of the silicon substrate. The insulating film 102 is, for example, a silicon oxide film.

The movable electrode 112 movable in a vertical direction is disposed above the fixed electrodes 111. The movable electrode 112 comprises a slit (opening portion) 10. The slit 10 is provided in a center portion of the movable electrode 112. The movable electrode 112 comprises one end portion and the other end portion defined by the slit 10. The long side of the movable electrode 112 defined by the slit 10 is the one end portion (first bent portion A), and the side opposite to the one end portion is the other end portion (second bent portion B). That is, the fixed electrode 111 comprises a first one end portion and a first other end portion, and the movable electrode 112 comprises a first one end portion corresponding to the first one end portion, and a second other end portion corresponding to the first other end portion.

The one end portion of the movable electrode 112 includes bent portion (first bent portion) A which is bent toward the substrate 100 side (downside).

The bent portions A of the movable electrode 112 extend outside the one end portion of the fixed electrode 111. This is to prevent the bent portions A of the movable electrode 112 from contacting a capacitor insulating film on the upper surfaces of the fixed electrodes 111 in the pull-in state and the down state.

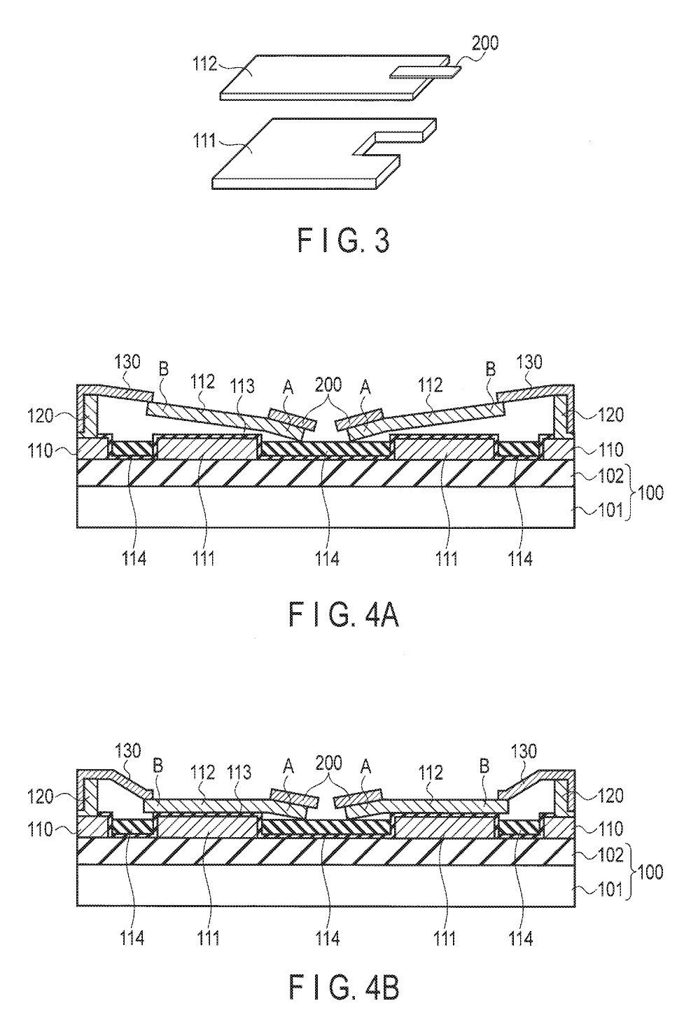

Dummy spring portions 200 are provided on the bent portions A of the movable electrode 112. The dummy spring portions 200 do not function as spring portions with respect to the movable electrode 112. A part of each dummy spring portion 200 extends outside the bent portion A. The fixed electrodes 111 are not formed under the dummy spring portions 200. As shown in FIG. 1, portions of the fixed electrodes 111 located under the dummy spring portions 200 each have an indented shape. The indented shape is shown in a perspective view of FIG. 3. In FIG. 3, the bent portion A is omitted.

In contrast, the other end portion of the movable electrode 112 is connected to anchor portions 120. The anchor portions 120 are connected to interconnects 110 provided on the substrate 100. As shown in FIG. 1 and FIG. 2, the fixed electrodes 111 do not overlap the spring portions 130.

A capacitor insulating film 113 is provided on the upper and side surfaces of the fixed electrodes 111. The capacitor insulating film 113 is provided on the insulating film 102. A buried insulating film 114 is provided between the adjacent fixed electrodes ill. The buried insulating film 114 is also provided between the interconnects 110 and the fixed electrodes 111. In the present embodiment, the upper surface of the buried insulating film 114 is lower than the upper surfaces of the fixed electrodes 111. However, the upper surface of the buried insulating film 114 may be higher than the upper surfaces of the fixed electrodes 111.

FIG. 4A is a cross-sectional view showing the MEMS device of the embodiment in the pull-in state. FIG. 4B is a cross-sectional view showing the MEMS device of the embodiment in the down state.

As shown in FIG. 4A, in the pull-in state, the bent portions A of the movable electrode 112 contact the buried insulating film 114. Before the bent portions A contact the buried insulating film 114, a portion of the movable electrode 112 other than the bent portions A (i.e., a main body portion) does not contact the capacitor insulating film 113 and the buried insulating film 114. That is, in the pull-in state, edges of the bent portions A of the movable electrode 112 are prevented from contacting the capacitor insulating film 113 on the upper surfaces of the fixed electrodes 111. In addition, in the pull-in state, the capacitor insulating film 113 at upper edges E of the fixed electrodes 111 is also prevented from contacting the main body portion of the movable electrode 112.

If the edges of the movable electrode 112 contact the capacitor insulating film 113 on the upper surfaces of the fixed electrodes 111, an electric field is concentrated at the edges of the movable electrode 112. As a result, electric charge tends to be accumulated between the edges of the movable electrode 112 and the fixed electrodes 111 under the edges. Such accumulation of the electric charge may cause stiction. In the present embodiment, the edges of the movable electrode 112 are the edges of the bent portions A, and the edges of the bent portions A do not contact the capacitor insulating film 113 on the upper surfaces of the fixed electrodes 111. In addition, in the pull-in state, the charge also tends to be accumulated when the capacitor insulating film 113 at the upper edges E of the fixed electrodes 111 contacts the main body portion of the movable electrode 112. In the present embodiment, however, such contact is prevented as described above. Therefore, occurrence of stiction is limited in the present embodiment.

Moreover, in the pull-in state and the down state, collision of edges (acute-angled portions) of the one end portion or the other end portion of the movable electrode 112 with the capacitor insulating film 113 may produce a foreign object. The foreign object includes at least one of a material of the movable electrode 112 and a material of the capacitor insulating film 113. If the foreign object is piled up on the capacitor insulating film 113 on the upper surfaces of the fixed electrodes 111, the foreign object may exist between the fixed electrodes 111 and the movable electrode 112 in the down state. Such a state where the foreign object exists may cause capacitance decrease of a capacitor.

In the present embodiment, however, since the edges of the one end portion and the other end portions of the movable electrode 112 do not collide with the capacitor insulating film 113 in both the pull-in state and the down state, the foreign object described above is not produced. As a result, capacitance decrease of the capacitor caused by the presence of a foreign object on the capacitor insulating film 113 on the upper surfaces of the fixed electrodes 111 can be prevented.

Therefore, according to the present embodiment, the MEMS device capable of preventing performance degradation can be provided.

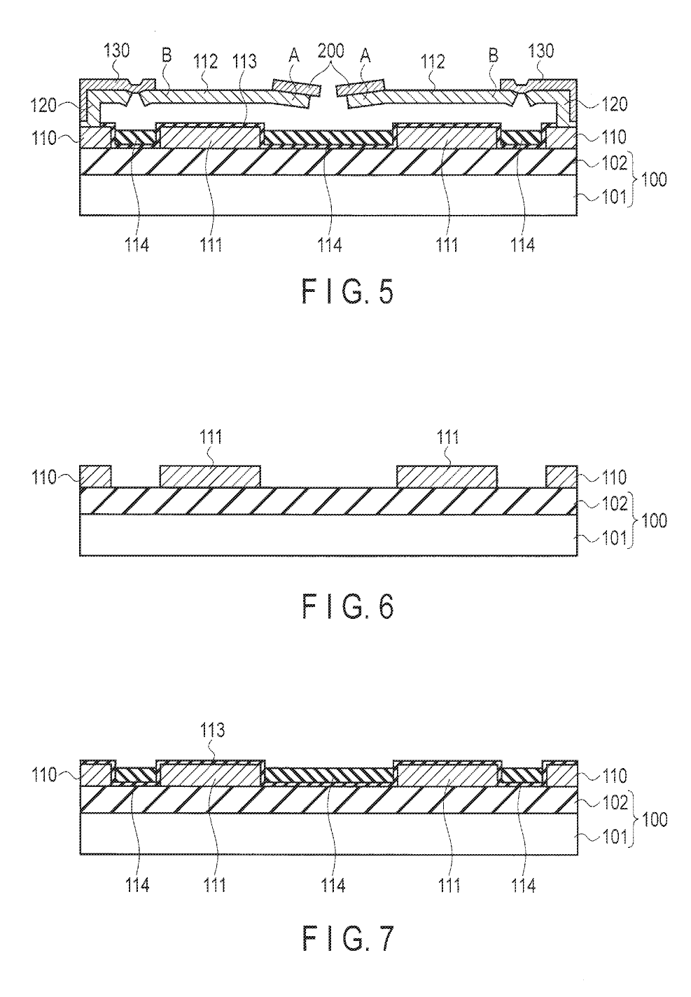

FIG. 5 is a cross-sectional view showing a modified example of the MEMS device of the first embodiment. In the modified example, each other end portion of the movable electrode 112 includes a bent portion B, and an end portion of the anchor portion 120 adjacent to the bent portion B also includes a bent portion.

FIG. 6 to FIG. 14 are cross-sectional views showing a method for manufacturing the MEMS device shown in FIG. 5.

[FIG. 6]

Interconnects 110 and fixed electrodes 111 are formed by forming an insulating film 102 on a semiconductor substrate 101, forming a conducting layer on the insulating film 102, and then processing the conducting layer by using photolithographic process and etching process.

[FIG. 7]

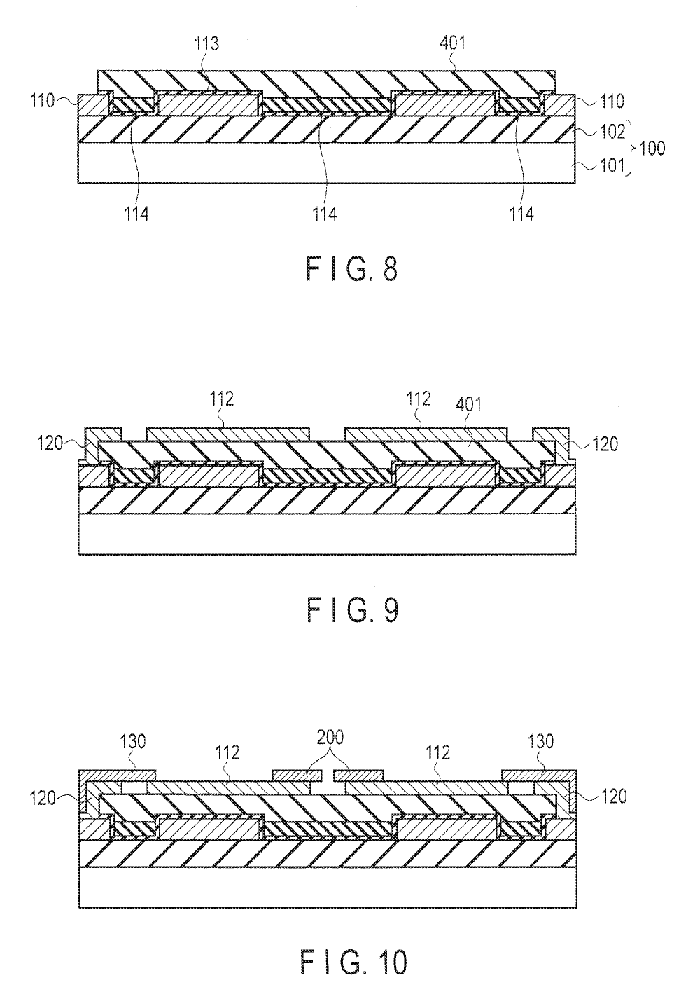

A capacitor insulating film 113 is formed on exposed surfaces of the insulating film 102, the interconnects 110 and the fixed electrode ill. Next, a buried insulating film 114 is formed between the adjacent fixed electrodes 111 and between the interconnects 110 and the fixed electrodes 111 by forming an insulating film on the capacitor insulating film 113 and polishing the insulating film by using chemical mechanical polishing (CMP) process.

[FIG. 8]

A first sacrificial film 401 is formed on the capacitor insulating film 113 and the buried insulating film 114. Then, a part of the capacitor insulating film 113 and the first sacrificial film 401 on the interconnects 110 are removed by using photolithographic process and etching process. The first sacrificial film 401 is, an insulating film containing an organic substance such as polyimide as a material.

[FIG. 9]

A movable electrode 112 and anchor portions 120 are formed by forming a conducting layer on the interconnects 110 and the first sacrificial film 401 and then processing the conducting layer by using photolithographic process and etching process.

[FIG. 10]

Spring portions 130 and dummy spring portions 200 are formed by forming an insulating film in a region including the movable electrode 112 and the anchor portions 120 and then processing the insulating film by using photolithographic process and etching process.

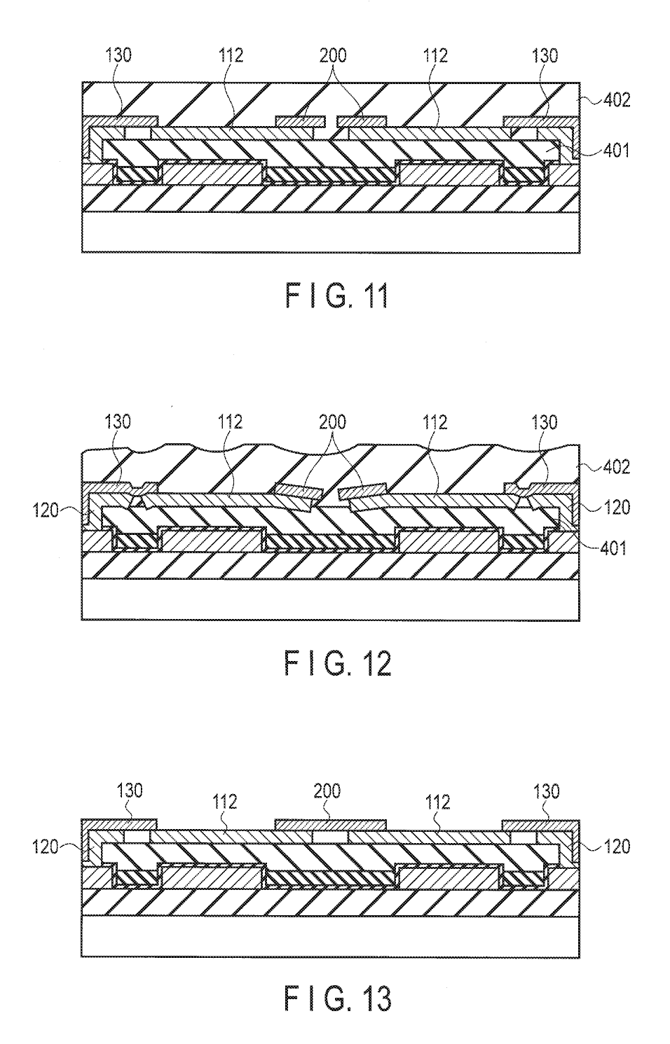

The insulating film is, for example, a silicon nitride film. The insulating film is formed so as not to fill gaps between the movable electrode 112 and the anchor portions 120 and a gap provided in the movable electrode 112.

[FIG. 11]

A second sacrificial film 402 is formed on the movable electrode 112, the spring portions 130 and the dummy spring portions 200. The second sacrificial film 402 is, for example, an insulating film containing an organic substance such as polyimide as a material.

[FIG. 12]

The sacrificial films 401 and 402 are subjected to curing. The curing is performed by, for example, heat treatment. The curing causes the sacrifice film 402 to shrink, and the shrunken sacrifice film 402 deforms laminated portions of the movable electrodes 112 and the dummy spring portions 200, and laminated portions of the anchor portions 120 and spring portions 130, which results in forming the bent portions at the end portions of the movable electrodes 112 and the anchor portions.

After that, the MEMS device shown in FIG. 5 is obtained by removing the sacrificial films 401 and 402.

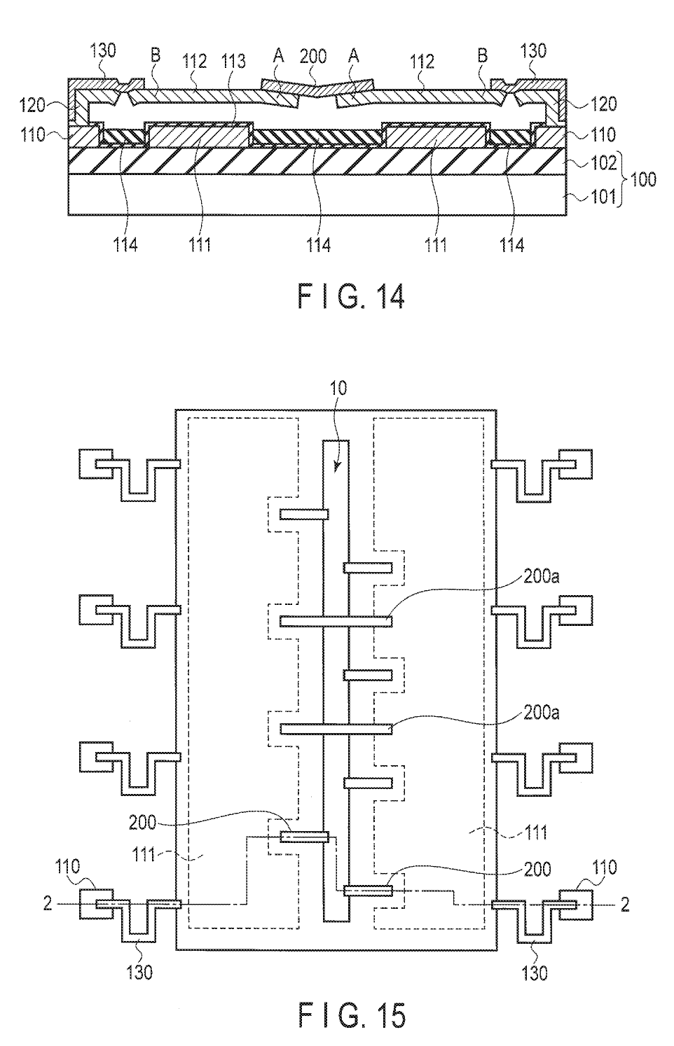

It is noted that the adjacent one end portions of the movable electrode 112 can be joined by a dummy spring portion 200a as shown in FIG. 14 by providing a dummy spring portion 200 as shown in FIG. 13 instead of providing the dummy spring portion 200 as shown in FIG. 10. That is, the dummy spring portion 200a can be used as a bridge portion provided across the slit 10 as shown in FIG. 15. A pull-in voltage can thereby be adjusted.

### Second Embodiment

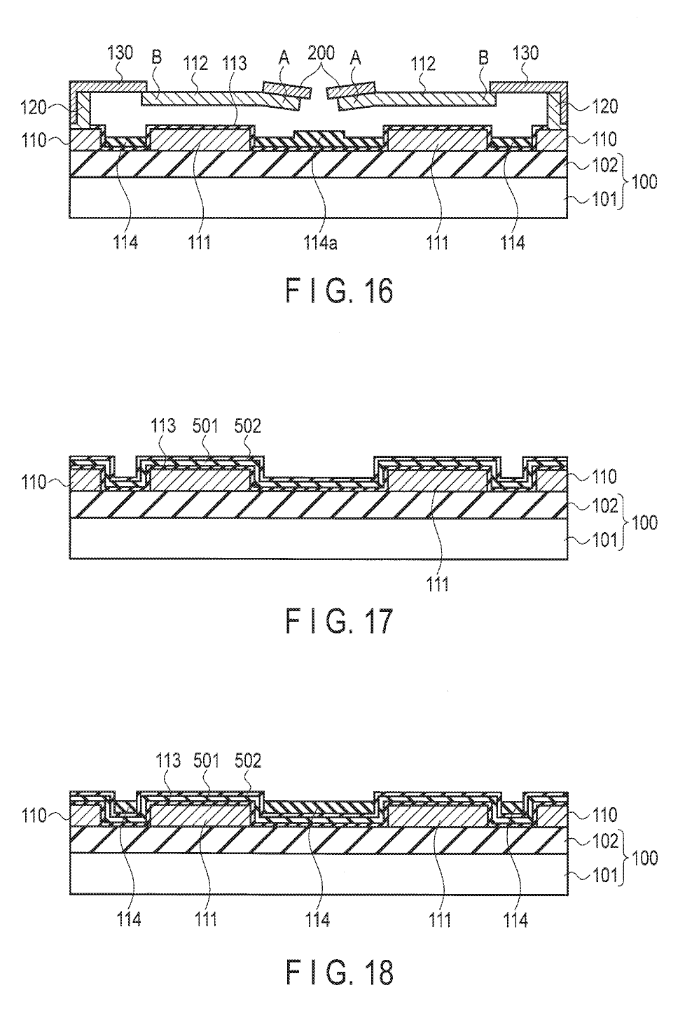

FIG. 16 is a cross-sectional view showing a MEMS device of a second embodiment and corresponds to FIG. 2 which is a cross-sectional view of the first embodiment seen along one-dot chain line 2-2 in FIG. 1.

The MEMS device of the present embodiment is different from the MEMS device of the first embodiment in that a buried insulating film 114a comprises a convex portion, and the bent portions A of the movable electrode 112 contact the convex portion of buried insulating film 114a in the pull-in state and the down state.

According to the present embodiment, the bent portions A of the movable electrode 112 can easily contact the buried insulating film 114 by adjusting a height of the convex portion of the buried insulating film 114, even if a degree of bending of the bent portions A of the movable electrode 112 is small.

FIG. 17 to FIG. 21 are cross-sectional views showing a method for manufacturing the MEMS device of the present embodiment.

[FIG. 17]

After the process of FIG. 6, a capacitor insulating film 113 is formed. Next, a buffer insulating film 501 and a stopper insulating film 502 are sequentially formed on the capacitor insulating film 113. In the present embodiment, the explanation is set forth in a case where the capacitor insulating film 113, the buffer insulating film 501 and the stopper film 502 are, respectively, a silicon nitride film, a silicon oxide film and a silicon nitride film.

[FIG. 18]

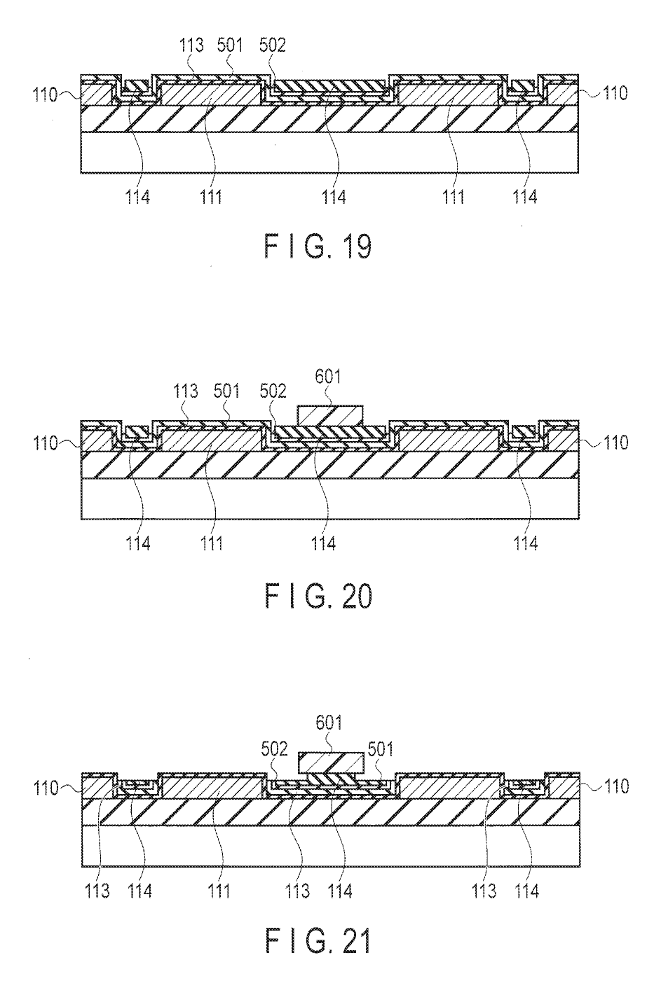

A buried insulating film (silicon oxide film) 114 is formed by forming a silicon oxide film on the stopper insulating film 502 and then polishing the silicon oxide film by CMP process using the stopper insulating film 502 as a stopper.

[FIG. 19]

Exposed portions of the stopper insulating film 502 are removed by downflow etching process. At this time, the upper part of the stopper insulating film 502 between the buried insulating film 114 and the buffer insulating film 501 is removed by the etching.

[FIG. 20]

A resist pattern 601 is formed on the buried insulating film 114 between the fixed electrodes 111.

The resist pattern 601 is formed in a region corresponding to a region to be the convex portion of the buried insulating film 114a.

[FIG. 21]

The buried insulating film 114 is subjected to a wet etching using a resist pattern 601 as a mask. As etchant, a solution with a high etching rate of silicon oxide to silicon nitride, for example, a solution including hydrofluoric acid is used.

As a result of the wet etching, a portion of the buried insulating film 114 not covered with the resist pattern 601 between the fixed electrodes 111 is etched and reduced in height. Moreover, a height of the buried insulating film 114 under the outer periphery of the resist pattern 601 is also reduced. Similarly, a height of the buried insulating film 114 between the interconnects 110 and the fixed electrodes 111 is reduced. Since portions of the buffer insulating film 501 provided on the upper surfaces of the interconnects 110 and the fixed electrodes 111 in FIG. 20 are relatively thin, these portions are removed. Since portions of the buffer insulating film 501 provided on the side surfaces of the interconnects 110 and the fixed electrodes 111 in FIG. 20 are relatively thick, the upper part of the portions is removed but the lower part is left.

After that, the resist pattern 601 is removed. The structure without the resist pattern 601 corresponds to the structure in FIG. 7, so that the MEMS device shown in FIG. 16 is obtained by further performing processes conformed to the processes in FIG. 8 to FIG. 13.

The MEMS device of the present embodiment also includes modified examples corresponding to the modified examples of the first embodiment shown in FIG. 5, FIG. 14 and FIG. 15.

### Third Embodiment

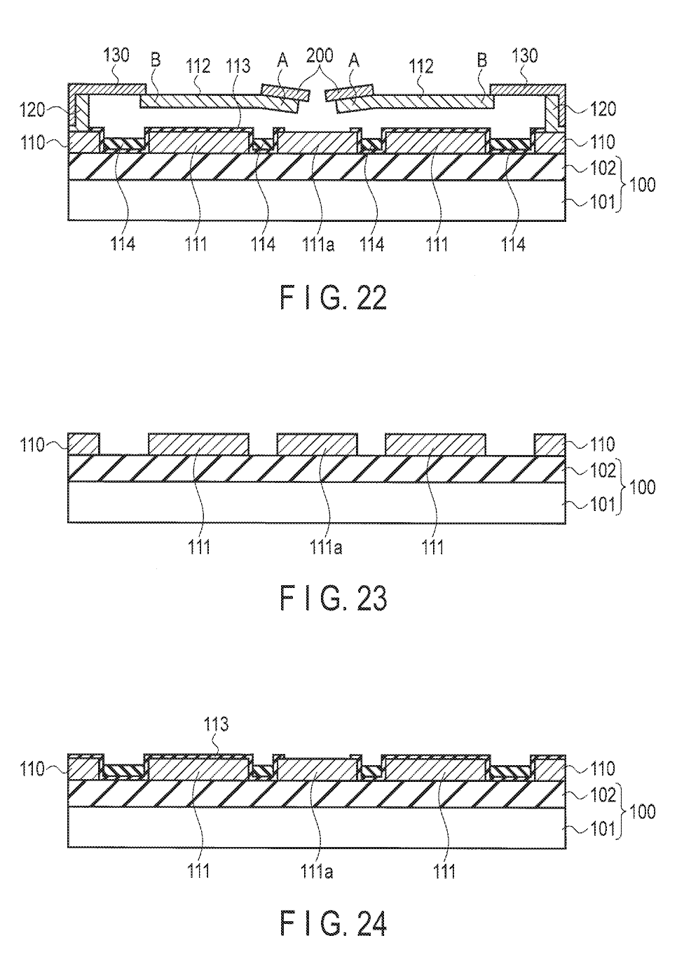

FIG. 22 is a cross-sectional view showing a MEMS device of a third embodiment and corresponds to FIG. 2 which is a cross-sectional view of the first embodiment seen along one-dot chain line 2-2 in FIG. 1.

The MEMS device of the present embodiment is different from the MEMS device of the first embodiment in that a dummy fixed electrode 111a is provided between the adjacent fixed electrodes 111, and the bent portions A of the movable electrode 112 contact the dummy fixed electrode 111a before the main body portion of the movable electrode 112 contact the dummy fixed electrode 111a in the pull-in state and the down state. The dummy fixed electrode 111a electrically floats state.

To manufacture the MEMS device of the present embodiment, for example, a dummy fixed electrode 111a is first formed as shown in FIG. 23 in the process of FIG. 6 of the first embodiment, next, a capacitor insulating film 113 is formed on an entire surfaces as shown in FIG. 24, and then a portion of the capacitor insulating film 113 in a region (region including a portion to contact the bent portions A of the movable electrode) on the upper surface of the dummy fixed electrode 111a is removed. The structure shown in FIG. 24 corresponds to the structure of the first embodiment shown in FIG. 7, so that the MEMS device shown in FIG. 22 is obtained by further performing processes conformed to the processes in FIG. 8 to FIG. 13.

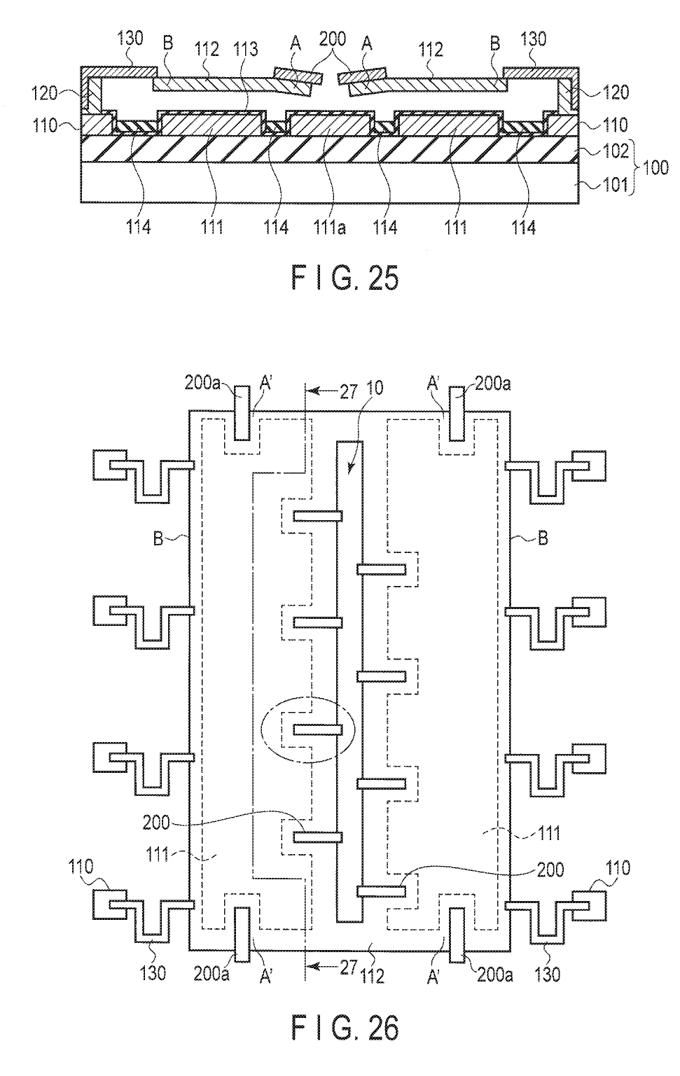

It is noted that the capacitor insulating film may be provided on the entire upper surface of the dummy fixed electrode 111a as shown in FIG. 25.

The modified examples of the first embodiment shown in FIG. 5, FIG. 14 and FIG. 15 are applicable to the present embodiment, too.

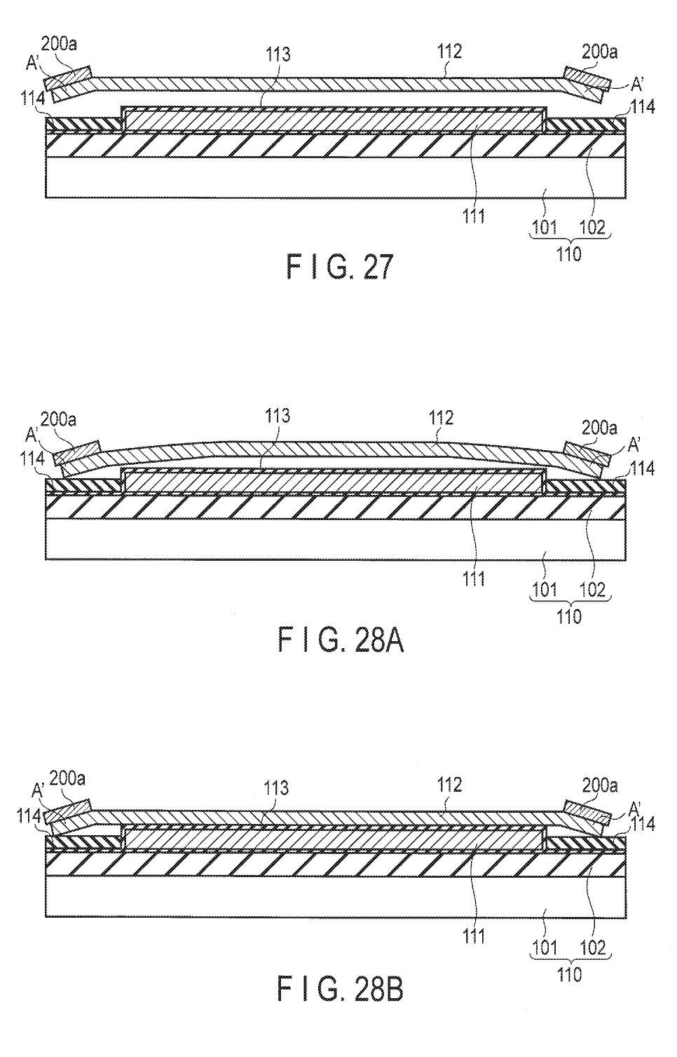

In addition, end portions of the movable electrode on the short sides may include bent portions in any of the first to third embodiments. For example, in the first embodiment, as shown in FIG. 26 and FIG. 27, both end portions of the movable electrode 112 on the short sides may include bent portions A′. The bent portions A′ correspond to the end portions of the movable electrode 112 on the short sides defined by the slit 10. It is noted that FIG. 26 and FIG. 27 correspond to FIG. 1 and FIG. 2 of the first embodiment, respectively.

When the bent portions A′ are included, as shown in FIG. 28A and FIG. 28B, edges of the bent portions A′ on the short sides of the movable electrode 112 do not collide with the capacitor insulating film 113 in both the pull-in state and the down state. Therefore, the same effect and advantage as the case of including the bent portions A can be achieved. It is noted that FIG. 28A and FIG. 28B correspond to FIG. 4A and FIG. 4B of the first embodiment, respectively.

Moreover, the end portions of the movable electrode 112 on the long sides do not necessarily include the bent portions as long as the end portions of the movable electrode 112 on the short sides include the bent portions instead.

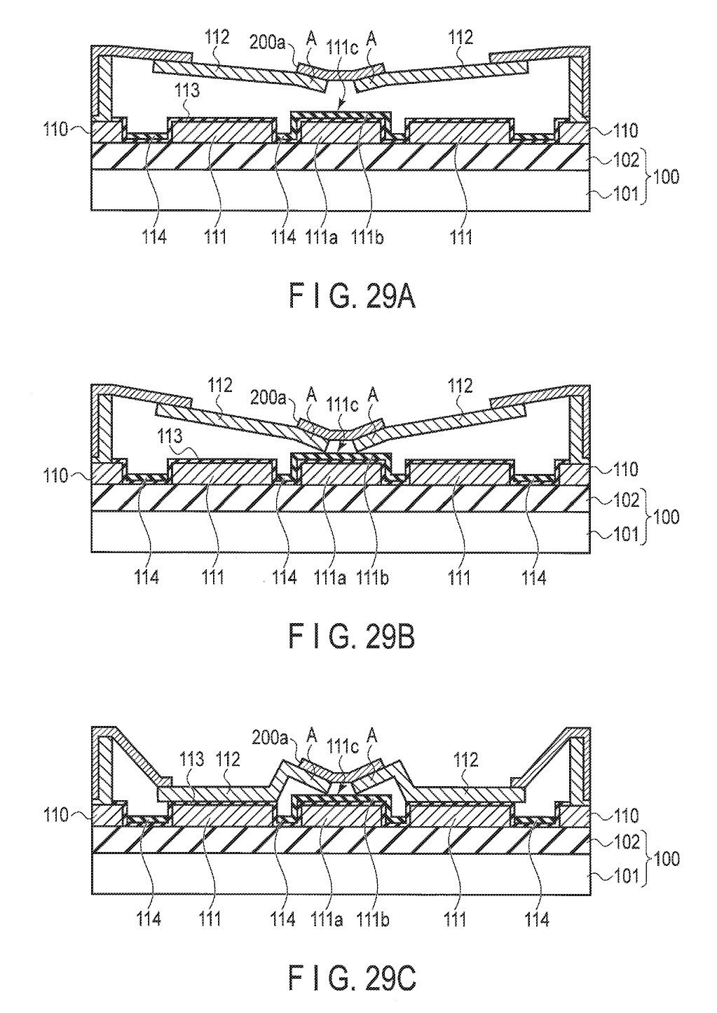

FIGS. 29A, 29B and 29C are a cross-sectional views showing a MEMS device of yet another embodiment.

FIGS. 29A, 29B and 29C are the MEMS device in an up state, pull-in state and down state, respectively. In the present embodiment, the dummy spring portion 200a shown in FIG. 15 is used, but the dummy spring portion 200 shown in FIG. 1 may be used.

The MEMS device of the present embodiment comprises a film (hereafter referred to as level raising film) 111b provided on the dummy spring portion 200a. The dummy spring portion 200a may be either an insulating film or a conductive film. In FIGS. 29A, 29B and 29C, the capacitor insulating film 114 is provided between the dummy fixed electrode 111a, and an upper surface of the dummy fixed electrode 111a is covered with the capacitor insulating film 114. However, as shown in FIG. 22, a part of the upper surface of the dummy fixed electrode 111a may be exposed.

Hereafter, the dummy fixed electrode 111a and the level raising film 111b will be referred to as “level-raised dummy fixed electrode 111c”.

A distance (space) between the level-raised dummy fixed electrode 111c and the bent portion A of the movable electrode 112 in the up state (FIG. 29A) is smaller than that of without the level raising film 111b.

The height of the dummy fixed electrode 111a is approximately same as the height of the fixed electrode 111. The height of the fixed electrode 111 is limited by design, so that the height of the fixed gate electrode 111a is not freely determined. As a result, the distance (space) between the dummy fixed electrode 111a and the bent portion A of the movable electrode 112 depends on the height of the fixed electrode 111. As the distance (space) between the dummy fixed electrode 111a and the bent portion A decreases, the main body portion of the movable electrode 112 is less likely to contact with the capacitor insulating film 113 on the upper surface of the fixed electrode.

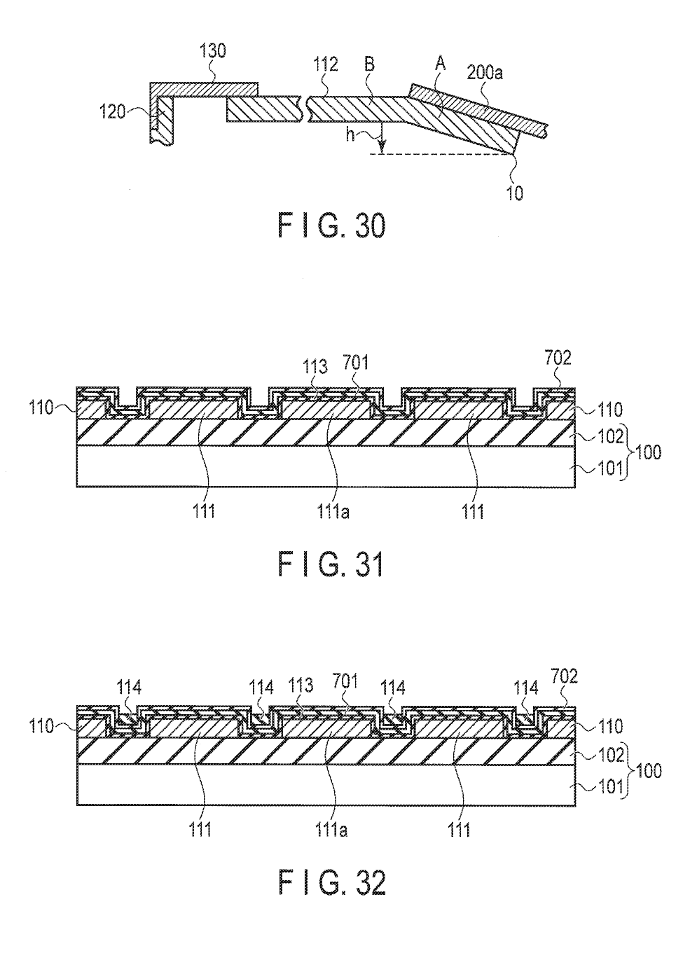

The distance (space) between the dummy fixed electrode 111a and the movable electrode 112 also depends on degree of the bend of the bent portion A. The degree of the bent portion A is defined by, for example, as shown FIG. 30, the distance h which is from a lower surface of the main body portion B of the movable electrode 112 to an edge 10 of a lower surface of the dummy fixed electrode 111a.

When the degree of the bent portion A is increased, the distance between the dummy fixed electrode 111a and the bent portion A is decreased, so that the edge of the bent portion A is suppressed from contacting the capacitor insulating film 113 on the upper surface of the fixed electrode.

Here, the present inventors find out that a variation of the degree of the bend (h) of the bent portion A is larger than a variation of the height of the dummy fixed electrode 111a. The reason is considered as follows. That is, the process forming the bent portion A includes the step of curing the sacrificial films (FIG. 12), which is not included in the process forming the dummy fixed electrode 111a. Similarly, it is confirmed that a variation of the degree of the bend of the bent portion A is larger than a variation of the height of the level-raised dummy fixed electrode 111c.

Therefore, employing the level-raised dummy fixed electrode 111c is effective to suppress the edge of the bent portion A from contacting the capacitor insulating film 113 on the upper surface of the fixed electrode 111.

FIG. 31 to FIG. 35 are cross-sectional views showing a method for manufacturing the MEMS device of the present embodiment.

[FIG. 31]

After the process of FIG. 6, a capacitor insulating film 113 is formed. Next, an insulating film 701 and a stopper insulating film 702 are sequentially formed on the capacitor insulating film 113. In the present embodiment, the explanation is set forth in a case where the capacitor insulating film 113, the insulating film 701 and the stopper insulating film 702 are, respectively, a silicon nitride film, a silicon oxide film and a silicon nitride film. The insulating film 701 on the dummy gate electrode 111a corresponds to the level raising film 111b in FIG. 29A. A conductive film may be used instead of the insulating film 701.

[FIG. 32]

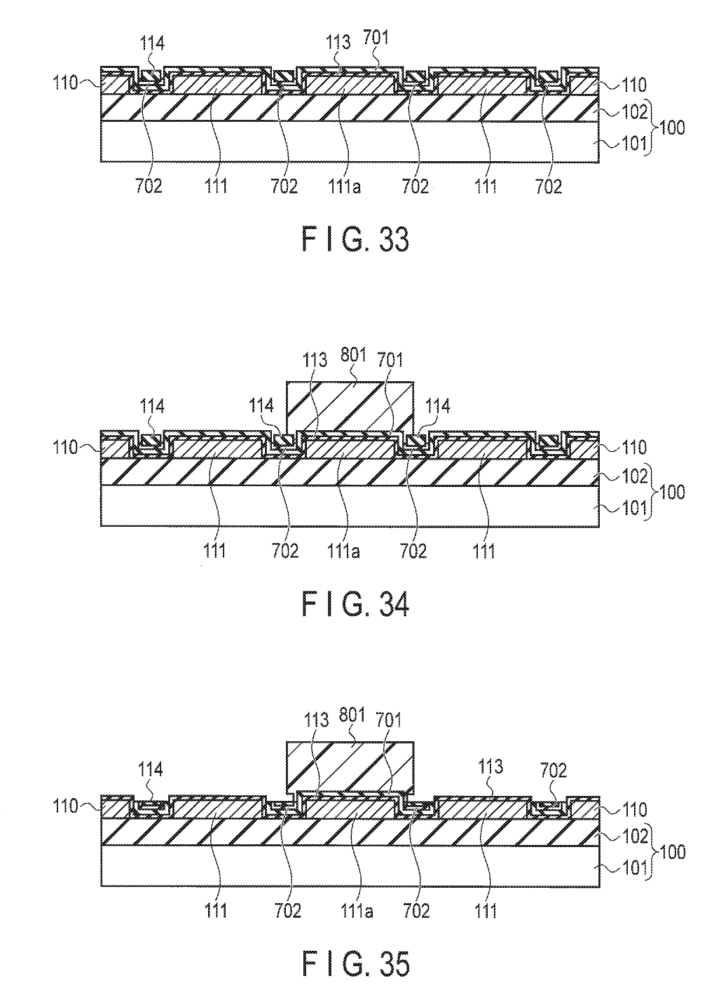

A buried insulating film (here, a silicon oxide film) 114 is formed by forming a silicon oxide film on the stopper insulating film 702 and then polishing the silicon oxide film by CMP process using the stopper insulating film 502 as a stopper. The buried insulating film 114 is formed between the fixed electrode 111 and the dummy gate electrode 111a. The buried insulating film 114 is further formed between the interconnects 110 and the fixed electrode 111.

[FIG. 33]

Exposed portions of the stopper insulating film 702 are removed by downflow etching process. At this time, the upper part of the stopper insulating film 702 between the buried insulating film 114 and the insulating film 702 is removed by the etching.

[FIG. 34]

A resist pattern 801 is formed on the dummy gate electrode 111a, and on the stopper insulating film 702 and the buried insulating film 114 which are peripheral of the dummy gate electrode 111a. The resist pattern 601 is formed in a region corresponding to a region to be the level raising film 111b.

[FIG. 35]

The buried insulating film 114 is subjected to a wet etching using a resist pattern 801 as a mask. As etchant, a solution with a high etching rate of silicon oxide to silicon nitride, for example, a solution including hydrofluoric acid is used.

As a result of the wet etching, a portion of the buried insulating film 114 not covered with the resist pattern 801 is etched and reduced in height. Moreover, in FIG. 34, portions of the insulating film 701 provided on the upper surfaces of the interconnects 110 and the fixed electrodes 111 are relatively thin, so that the portions are removed. Meanwhile, portions of the insulating film 701 disposed on the side surfaces of the interconnects 110 and the fixed electrodes 111 are relatively thick, so that the upper part of the portions is removed but the lower part is left.

It is noted that an isotropic etching such as downflow etching is used instead of the wet etching when a conductive film is used instead of the insulating film 701.

After that, the resist pattern 801 is removed. The structure without the resist pattern 801 corresponds to the structure in FIG. 7, so that the MEMS device shown in FIG. 29A is obtained by further performing processes conformed to the processes in FIG. 8 to FIG. 13.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a substrate;
a first electrode fixed on the substrate, and comprising a first one end portion and a first other end portion;
a capacitor insulating film provided on the first electrode;
an insulating film provided on the substrate and located around a periphery of the first electrode; and
a second electrode provided above the first electrode and movable, and comprising a second one end portion corresponding to the first one end portion and a second other end portion corresponding to the first other end portion, the second one end portion extending outside the first one end portion and comprising a first bent portion bent downward.

2. The device according to claim 1, wherein the first bent portion contacts an upper surface of the insulating film without contacting the capacitor insulating film when the second electrode is moved downward.

3. The device according to claim 1, wherein the insulating film comprises a convex portion.

4. The device according to claim 1, wherein the first electrode comprises a region having an indented shape, and the first bent portion is located above the region.

5. The device according to claim 1, further comprising a member provided on the first bent portion.

6. The device according to claim 5, further comprising a spring portion connected to the second other end portion, wherein a material of the member is same as a material of the spring portion.

7. The device according to claim 6, further comprising an anchor portion provided on the substrate and connected to the second other end portion via the spring portion.

8. The device according to claim 1, wherein the second electrode comprises a slit.

9. The device according to claim 8, wherein the second one end portion corresponds to a long side of the second electrode defined by the slit.

10. The device according to claim 8, further comprising a bridge portion provided across the slit.

11. The device according to claim 8, further comprising a bridge portion provided across the slit, wherein a material of the bridge portion is same as a material of the member.

12. The device according to claim 1, wherein the second other end portion extends outside the first other end portion.

13. The device according to claim 12, wherein the second other end portion does not contact the capacitor insulating film when the second electrode is moved downward.

14. The device according to claim 1, wherein the second other end portion extends outside the first other end portion, and comprises a second bent portion bent downward.

15. The device according to claim 1, further comprising a third electrode provided on the substrate, wherein an edge of the first bent portion is located above an upper surface of the third electrode.

16. The device according to claim 15, wherein the third electrode electrically floats.

17. The device according to claim 15, wherein a material of the third electrode is same as a material of the first electrode.

18. The device according to claim 15, wherein the upper surface of the third electrode and an upper surface of the first electrode are even in height.

19. The device according to claim 15, further comprising a film provided on the third film.

20. The device according to claim 15, wherein the capacitor insulating film is further provided between the third electrode and the film.
